(19) United States
(12) Patent Application Publication
(10) Pub. No.: US 2009/0017284 A1
(43) Pub. Date: Jan. 15, 2009

(54) DEVICE COMPRISING A CHARGE TRANSFER CHANNEL AND METHOD FOR MANUFACTURING THE SAME

(75) Inventors: Chiara Dionigi, Bologna (IT); Pablo Stoliar, Bologna (IT); Fabio Biscarini, Bologna (IT)

Correspondence Address: CANTOR COLBURN, LLP, 20 Church Street, 22nd Floor, Hartford, CT, 06103, US

(73) Assignee: CONSIGLIO NAZIONALE DELLE RICERCHE, ROMA (IT)

(21) Appl. No.: 12/161,854

(22) PCT Filed: Jan. 22, 2007
(86) PCT No.: PCT/EP2007/000502

§ 371 Date: Jul. 23, 2008

(30) Foreign Application Priority Data
Jan. 23, 2006 (IT) MI2006A000104

(51) Int. Cl. B32B 3/26; B05D 5/12; H01L 51/40

(52) U.S. Cl. 428/306.6; 427/58; 438/99; 257/E51.027

(57) ABSTRACT

A device comprising a charge transfer channel, wherein the charge transfer channel comprises a composite material which comprises particles of a dielectric material with interstice voids between them which are partially or totally infilled by a semiconductor or conductor material.

### TECHNICAL FIELD

The present invention relates to a device comprising a charge transfer channel, a method for manufacturing such device, a material for use in the channel of such device and a method for preparing such material.

### BACKGROUND ART

Devices which comprise a charge transfer channel, for example diodes and transistors, particularly light-emitting transistors and diodes, and field effect transistors, are well-known, and so are the methods for the manufacture thereof.

However, manufacture of these devices often requires complex tools and/or particular operating conditions. For example, the manufacture of known field-effect transistors requires the use of techniques such as spin-coating or ultra-high vacuum deposition.

The aim of the present invention is to eliminate the drawbacks noted above in conventional devices containing a charge transfer channel, by providing a device which comprises a charge transfer channel with a performance which is comparable to that of known devices and which can be obtained by means of a manufacturing method which is simple and does not require particular tools and/or particular operating conditions.

In particular, an object of the present invention is to provide a device which comprises a charge transfer channel and a method for manufacturing such device by using simple and inexpensive tools, which can be performed in near-atmospheric conditions and even in atmospheric conditions.

### DISCLOSURE OF THE INVENTION

This aim and this and other objects, which will become better apparent hereinafter, are achieved by a device according to the present invention, comprising a charge transfer channel, wherein the charge transfer channel comprises a composite material, said composite material comprising particles of a dielectric material with interstice voids between them, said interstice voids being filled partially or totally by a semiconductor or conductor material.

In one of its aspects, the present invention further relates to the use of a composite material which comprises particles of a dielectric material with interstice voids between them which are filled partially or totally by a. semiconductor material in a charge transfer channel of a charge transfer device, for example a field-effect transistor, a diode, particularly a light-emitting diode, or a light-emitting transistor.

In another aspect, the present invention relates to a method for manufacturing a device comprising a charge transfer channel in which the charge transfer channel comprises a composite material which comprises particles and a dielectric material with interstice voids between them which are filled partially or totally by a semiconductor or conductor material according to the present invention, said method comprising the step of depositing a mixture of semiconductor or conductor material and particles of dielectric material on a solid surface between two or more electrodes.

In a further aspect, the present invention relates to a method for preparing a composite material for use in a device comprising a charge transfer channel according to the present invention, comprising the steps of:
forming a semiconductor or conductor material in the form of particles, clusters, fibrils or aggregates, in a liquid medium which contains a mixture of solvent-nonsolvent for said semiconductor or conductor material, said solvent or said nonsolvent being mixable and containing submicron particles of a dielectric material, said dielectric material being insoluble in said liquid medium, and
separating from said liquid medium containing said particles, clusters, fibrils or aggregates of semiconductor or conductor materials and said particles of dielectric material a deposit which forms a colloidal composite;
drying said colloidal composite.

In another aspect, the present invention relates to a composite material which can be obtained by means of a method for preparing a composite material according to the present invention.

### BRIEF DESCRIPTION OF THE DRAWINGS

The following example is given by way of non-limiting example for the present invention, with particular reference to an organic field-effect transistor with a charge transport channel which comprises beads of polystyrene (PS)/tetraethyl sexithiophene (H4T6).

FIG. 1: A) schematic model of the process for forming the colloidal composite from a colloidal suspension of beads and from a saturated solution of H4T6; B) deposition of the colloidal composite on an OFET. The drying process is capable of growing crystals of H4T6 within the tetrahedral cavities (the triangles represent the projections of the cavities).

FIG. 2: effect of the scavenging process on the part of 150-nm and 270-nm beads. The X and Y axes at the bottom and on the right refer to the process performed with 150-nm beads, while the top and left axes refer to 270-nm beads. The experiments for both sizes were performed in the experimental conditions, keeping constant the final volume of the colloidal dispersion. The samples are named and referenced in this way in the text in capital letters.

FIG. 3: top: optical image of dendritic domains in polarized light within the dry colloidal composite constituted by 150-nm beads and H4T6; bottom: SEM image of a typical domain (left) and an enlarged-scale view of a detail of said image (right);

FIG. 4: OFET which uses the composite C as channel; top: typical morphology of the colloidal composite with 150-nm PS after deposition on a transistor in which the 10-μm channel is functionalized with HMDS. In particular, the micropipette with dispersion of beads which approximates the test configuration for the deposition of the OFET is shown; bottom: transfer characteristic of the transistor.

FIG. 5: evolution of factors which compose the ON/OFF ratio of the transistor with respect to the initial H4T6/PS ratio. In the case of a composite with a quantity of H4T6 which is lower than the quantity present in B, an electrical percolation path does not form and therefore cannot be indicated in the chart. The increase in the quantity of H4T6 with respect to sample B improves the apparent mobility of the field effect of the composite, as shown by item C. Any further increase in the ratio of H4T6/PS mainly increases the mass conductivity, as shown in D. Finally, the ON/OFF ratio is simply controlled by the modulation of the depletion region. In the case of sample E, one is in flocculation conditions and modulation at the limit of detection is observed. The constant ON/OFF ratio lines are also presented.

FIG. 6: confocal microscope image at the excitation wavelength of λ=408 nm, showing the existence of large domains of H4T6 composites.

FIG. 7: working transistor channels in which dendritic domains were not found “optically” to form an electrical percolation layer between the well and the source.

### WAYS OF CARRYING OUT THE INVENTION

The composite material which can be used in the device comprising a charge transfer channel according to the present invention can be obtained for example from a precursor in the form of a solid, colloid, cell, fog or smoke.

The composite material used in the present invention has charge transport properties as, particularly, for the composite which contains semiconductor material, it can have for example a charge carrier mobility of more than 10⁻⁵ cm² Ws⁻¹, and for the composite material containing conductor material, it can have for example a conductivity of more than 10⁻¹⁰ S cm⁻¹.

The charge transport properties of the composite material used in the present invention can vary according to the ratio between the quantities of particulate dielectric material and semiconductor or conductor material and according to the dimensions of the particles of dielectric material. The composite material used in the present invention preferably comprises 10 to 50% by weight of semiconductor material or conductor material with respect to the weight of the dielectric particulate material.

The dielectric particulate material comprised in the composite material preferably has an average particle size of less than one micrometer, where said dimension is expressed as an arithmetic mean of the largest dimension of the particles. Advantageously, the average dimension of the particles of dielectric material ranges from one nanometer to one micrometer.

The dielectric material comprised in the composite material can be for example an organic dielectric material, such as a polymeric dielectric material, particularly polystyrene or polymethyl methacrylate or mixtures thereof.

Moreover, the dielectric material comprised in the composite material can also be an inorganic dielectric material, such as silicon oxide or aluminum oxide or mixtures and derivatives thereof.

The particles of dielectric material comprised in the composite material used in the present invention can be for example shaped like beads, cubes, polyhedrons, ellipsoids, parallelepipeds, fullerenes and/or conglomerates thereof.

Advantageously, the dielectric particulate material used in the method for preparing the composite material according to the present invention has a surface area (measured by SEM) of more than 1 m²/gram.

Conveniently, the dielectric material used has polar groups on its surface.

The semiconductor or conductor material comprised in the composite material used in the present invention can be for example a molecular material or a polymeric material.

In particular, the semiconductor or conductor material can be for example an organic semiconductor or conductor material, particularly a conjugated organic semiconductor material, such as nonfunctionalized or functionalized oligo- and polythiophenes with aliphatic chains and/or polar groups, nonfunctionalized or functionalized oligo- and polyacenes with aliphatic chains and/or polar groups, nonfunctionalized or functionalized rubrene with aliphatic chains and/or polar groups, nonfunctionalized or functionalized oligofluorenes with aliphatic chains and/or polar groups, and mixtures, composites and copolymers thereof such as polyethylene dioxythiophene, poly(3,4,ethylene dioxythiophene), poly(styrene sulfonate), polyanilines not doped or doped with Lewis acids which maintain their solubility, and polypyrroles.

Moreover, the semiconductor or conductor material comprised in the composite material used in the present invention can be for example an inorganic semiconductor or conductor material, in particular a semiconductor or conductor material selected from the group constituted by oxides of transition metals, carbon nanotubes, transition metal dichalcogenides and particles of transition metals.

The semiconductor or conductor material can be present in the composite material used in the present invention in a form selected for example among clusters, aggregates, fibrils and particles.

The semiconductor or conductor material can be present in the interstice voids between the particles of dielectric material of the composite material used in the present invention in amorphous or crystalline form.

Examples of devices comprising a charge transfer channel according to the present invention are field effect transistors, diodes, particularly a light-emitting diode, and a light-emitting transistor.

The method for manufacturing a device comprising a charge transfer channel according to the present invention does not require particular temperature, pressure or environmental operating conditions. In particular, the deposition step of the process can also be performed in air, even at ambient temperature and pressure.

Moreover, the step for deposition of said mixture, which can be in the form of a colloid or gel, can be performed with a simple and inexpensive deposition technique, selected for example among contact printing, soft lithography techniques, drop casting, inkjet printing, spray-dry, microfluidics and injection.

The mixture of material in colloidal form can be dried in order to obtain a solid composite material. Drying can occur in any suitable condition, advantageously even in air, at atmospheric temperature and pressure.

The method for preparing the composite material according to the present invention can comprise in particular the steps of:

a. forming a colloidal dispersion of said dielectric particulate material with an average particle size of less than one micron in a liquid in which said dielectric material is insoluble;

b. forming a solution of said semiconductor or conductor material in one or more solvents for said semiconductor or conductor material, said one or more solvents being mixable with said liquid, said semiconductor or conductor material being insoluble in the liquid;

c. mixing the dispersion and the solution, thus obtaining a mixture which contains particles, clusters, fibrils or aggregates of semiconductor or conductor material in a liquid medium which contains one or more solvents of the semiconductor or conductor material and the liquid, and in which particles of dielectric material are present; and

d. separating from said mixture a supernatant and a deposited material which forms the colloidal composite material.

Advantageously, the semiconductor material used is an organic semiconductor material.

Conveniently, the solution used is a supersaturated solution at ambient temperature of the semiconductor or conductor material, the solution and the dispersion are heated before mixing to a temperature at which the semiconductor or conductor material is completely dissolved in the one or more solvents, and the mixture is brought to ambient temperature before separation.

Separation can be performed for example by centrifugation, filtration or decantation.

The one or more solvents used can be, for example, selected from the group constituted by tetrahydrofuran, methanol, ethanol, propanol isopropanol and acetone.

The dispersion used in the method for preparing the composite material according to the present invention can have for example a concentration of dielectric particulate material of more than 1.0 g/l; the solution used in the method according to the present invention can have for example a content of semiconductor or conductor material ranging from 0.01 g/l to 1 g/l.

The dispersion and the solution used in the method according to the present invention are mixed with a weight ratio preferably ranging from 10:90 to 90:10.

The colloidal composite obtained by means of the method according to the present invention preferably comprises 10 to 50% by weight of semiconductor or conductor material with respect to the weight of the dielectric particulate material.

In one embodiment, the present invention relates to organic field effect transistors (OFET).

Organic field effect transistors (OFET) are of considerable interest due to their impact on organic electronics, as base elements of digital logic circuits, rear panels of active-matrix displays, biochemical sensors and diagnostic units. Two types of conjugate materials have proved to be suitable as a semiconductor layer in OFET, divided into polymers and small-molecule materials.

Conjugated polymers can be processed by solutions which use standard processes of planar technology, such as for example spin-coating and inkjet printing [1], while small-molecule conjugated materials are often processed by sublimation in ultra-high vacuum [2, 3]. In general, molecular materials have a higher charge mobility than polymers.

It is a fact that charge transport is highly correlated to the morphology at higher scales of length, since charge transport occurs through the percolation lattice determined by the contours of the grains. Obtaining crystalline order on scales of length, possibly comparable with the channel length of the device, is an extremely difficult task for any established thin-film technology.

The problem of long-range correlations is still open, although research is aimed at a) depositing electrodes at the top of individual crystals or by means of a strategy which imitates the single-crystal approach b) matching the size of the domain with the length of the channel c) using self-organization at any scale of length, such as semiconductor discotic liquid crystals. However, these approaches are technologically demanding and are often influenced by uncontrolled interrelations of kinetic and thermodynamic factors.

One embodiment of the present invention provides a process for manufacturing OFET which is simple and reproducible and in which an organic semiconductor material, such as a molecular organic material, deposited from a solution, self-organizes in an active state which has both high molecular order and better transistor performance.

The method for manufacturing OFET according to the present invention entails the use of a mesoscopic template made of beads of dielectric material, which are preferably monodispersed, and assembled, their surface being decorated with a soluble organic semiconductor, such as a soluble molecular semiconductor, for example tetrahexyl sexithiophene (H4T6) [4].

The beads can act as carriers for the semiconductor, such as H4T6, and provide the molecules in close proximity to the dielectric surface of the transistor channel. The set of beads determines the mesoscale and nanoscale channels which behave as micro-incubators for the semiconductor crystals.

With the process according to the invention it is possible to control two different scales of time and length: i) over a short time (minutes), a densely packed template with mesoscopic length scales forms; ii) over longer times (hours), the molecules are guided by the evaporation of the liquid phase and flow within the channels of the template until they organize in molecularly ordered domains, some of which are in contact with the substrate. This slow process introduces molecular order and supramolecular length scales.

The literature reports several chemical methods for synthesizing core-shell beads [5-11].

A particular embodiment of the present invention, in which the composite material comprises nanospheres of polymeric dielectric material and H4T6 as semiconductor material is described hereafter by way of illustration.

Highly hydrophobic interactions occur between H4T6 and polymeric nanospheres in a hydrophilic medium. H4T6 is a semiconductor oligomer, which is stable in the solid phase in normal conditions. It is insoluble in water, partially soluble in ethanol (≈0.5 mg/ml) and fully soluble in an organic solvent such as acetone. When an acetone/ethanol solution of H4T6 is mixed with the aqueous dispersion of beads, nucleation begins. The dimensions of the nuclei depend on the balance between the energy contributions of the solid/liquid interface and on the forming crystalline phase.

The relative quantity of the initial mixture of water/organic material is a critical parameter for nuclei formation, for stability and for size.

These “clusters” are collected by means of polystyrene nanospheres (hereinafter termed PS), which act as scavengers [12] which are highly hydrophobic at the surface, and a stable colloidal dispersion of decorated beads forms. The colloidal dispersion in decorated nanospheres is stable in mixtures at 80% of water/organic solvent, such as for example a mixture of ethanol/acetone. The decorated beads are separated from the liquid phase by centrifugation.

The separation of substances from a fluid phase on the surface of the solid substrate is believed commonly to depend on parameters such as for example the concentration of the substance and the surface adsorption properties, such as for example the area and polarity of the surface.

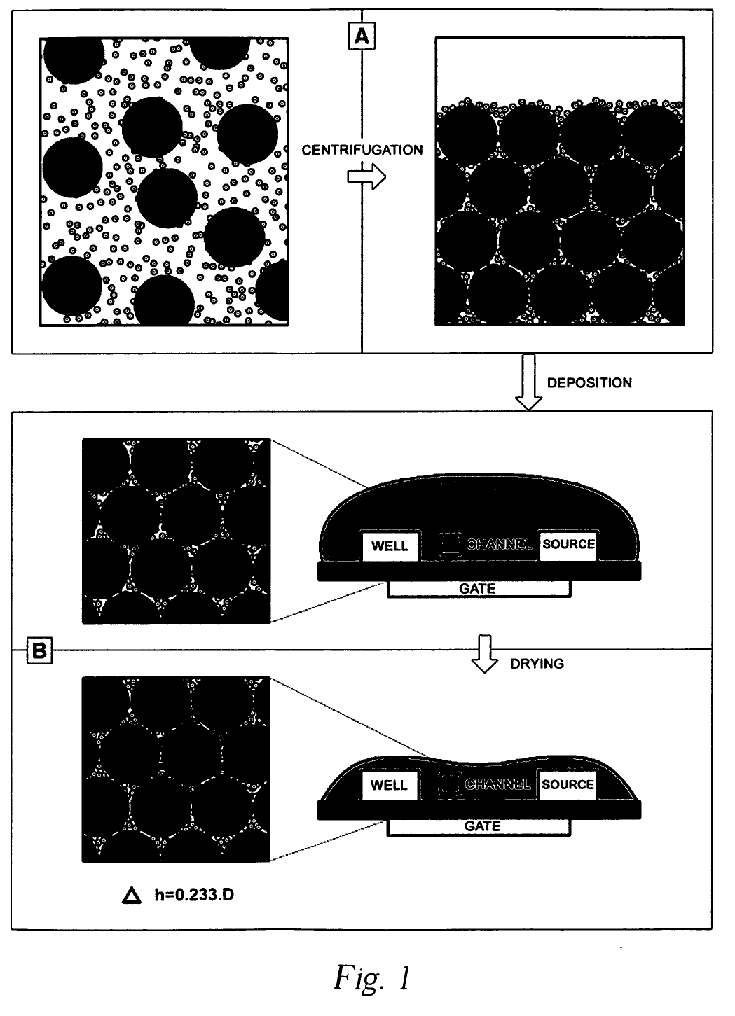

One can hypothesize a scavenging process which is similar to the one described in the literature [6-10] and shown in FIG. 1A. PS collects clusters of H4T6 at the nucleation point directly after the mixing of the dispersion of aqueous PS and the solution of H4T6 in ethanol/acetone. During centrifugation, PS aggregate in a densely packed structure and the cluster of H4T6 carried by the beads preferably self-organizes in said structure, which is stabilized by filling the interstice void, see FIG. 1B. When a large quantity of H4T6 with respect to PS is used, the available surface of PS is not sufficient to collect the excess quantity of nuclei, which begin to coagulate independently of the bead aggregation process. Therefore, parasitic flocculation occurs simultaneously with the filling of the structure of beads with compact packing.

### EXAMPLE

Decoration of PS with H4T6

Both the synthesis of monodispersed PS and of H4T6 are reported elsewhere [4, 13].

The templating system used in this example is constituted by a colloidal dispersion in water of beads of polystyrene with an absolute diameter deviation of<10%.

The concentration of the beads is 9.75 10⁻⁴ g/ml. The dispersion, in the quantity of 20 ml, is thermostat-controlled at the temperature of 55° C.

The H4T6 oligomer selected has a solubility in ethyl alcohol at ambient temperature of 0.5 mg/ml and is fully soluble in acetone. The decoration of PS was performed by mixing 10 mg of H4T6 (previously dissolved in acetone/ethanol at 1:3 by volume) with an aqueous dispersion of PS which contains 20 mg of PS (D=150±4 nm, D=270±7). The final mixture of the solvent yielded 5:1 by volume of water/organic material.

The solution of H4T6 is prepared by dissolving completely H4T6 in acetone and then adding the minimum quantity of ethyl alcohol capable of inducing the forming of precipitate. The solution appears opaque. The container is then closed and brought to 55° C., a temperature at which the solution becomes clear again.

The dispersion of templating beads and the solution of the oligomer are then mixed, keeping the entire system at 55° C. during the operation.

After the time required by the system to return to ambient T (approximately 20 minutes) has elapsed, the composite mixture of PS/H4T6 is centrifuged at a centrifugal acceleration of >2800 g. The supernatant, which is transparent, is separated from the deposit. The deposit at ambient T (20° C.) again assumes a colloidal shape, dispersing again in the excess of liquid phase that has remained adsorbed on the deposit. The deposit assumes a highly viscous and reflective form, indicating a pseudo-ordered structure of the beads within the narrow liquid phase which contains PS/H4T6.

Decorated beads were separated from the liquid phase by centrifugation with an acceleration of 3000 g.

### Preparation of the Transistors

The OFET test configurations were prepared on a highly doped n-type silicon substrate which acts as gate, with an insulating layer of SiO₂, grown thermally with a thickness of 200 nm and is passivated by using hexamethyldisilizane (HMDS). The insulating layer has a capacity per unit of air of 17 nf/cm². Two pads of gold, evaporated with a thickness of 150 nm and interleaved (by using an appropriate adhesive layer) from well and source come into contact with, and form, a transistor channel (W) which is 1 mm wide, with a length (L) of 10 μm. Before deposition, the test configuration was cleaned by using boiling acetone and then acetone vapor and immediately dried by using filtered dry nitrogen.

A drop of approximately 1 μl was deposited (by using only a glass rod in contact with the drop) at the top of each test configuration. After drying, the material forms a hemispherical deposit which usually covers most of the test configurations with a thickness which varies of fractions of millimeters. If there is no complete covering, the value of the width of the channel has been corrected adequately.

Measurement of the Response of Transistors and Extraction of the Parameters

Extraction of mobility was performed from the transfer characteristic I_{d}=f(V_{gs}) in saturation conditions with the formula:

μₛₐₜ=(d_{Id}/d_{Vgs})²·2·L/(Cᵢ·W)

in which I_{d} is the well current, W and L are the width and length of the channel, μₛₐₜ is the mobility of the charge carriers in saturation conditions, Cᵢ is the capacitance of the dielectric layer per unit area, and V_{gs} is the gate-source potential. The mobility, the sub-threshold slope, the on/off ratio and the shift of the threshold voltage were extracted from the transfer characteristic for a well-source potential V_{ds}=−21V.

The transfer characteristic was measured in environmental conditions but in the dark. The values of the well current were measured by using a Keithley 6430 sub-femtoamperometer which also biased the channel. During acquisition, a Keithley 3930A multifunction synthesizer was connected to an in-house voltage amplifier, which varied at a rate of 100 V/s, supplying the gate voltage.

### RESULTS

As regards the material H4T6, experiments were carried out to check for the existence of an effect due to the size of the beads. Scavenging was performed in the same conditions with beads having a diameter of 270 nm and 150 nm.

The dried supernatant was dissolved in acetone and analyzed spectrophotometrically at λ=411 nm in order to determine the absorbed H4T6 from the residual H4T6 after the scavenging effect.

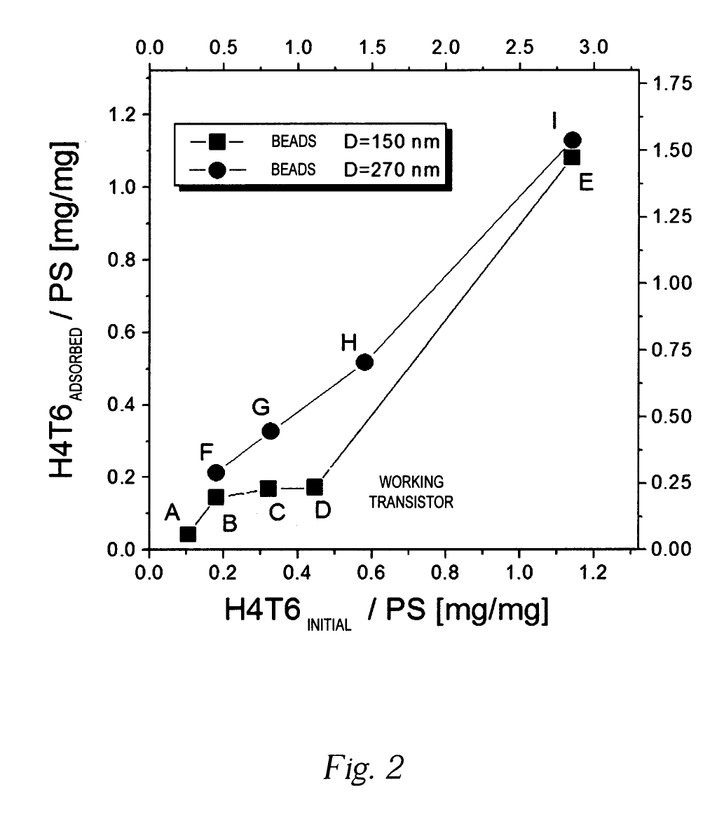

The relative quantity of H4T6 swept by PS of 150 and 270 nm is shown in FIG. 2.

It is evident from FIG. 2 that the PS scavenging process for the dispersion of H4T6 depends critically both on the dimensions of the beads and on the initial H4T6/PS ratio. With different types of semiconductor materials, the scavenging effect is effective with other values of the size of the beads and with other concentration values with respect to the ones shown in the example, in view of the dependency on the volume occupied by the semiconductor material (and therefore on its density; the density of H4T6 is approximately 1.1 kg/l) and on the dimensions of the clusters (in the case of H4T6, one has subnanometer dimensions) with respect to the dimensions of the cavities between the beads. As shown in FIG. 2, the 150-nm beads have constant scavenging in the range from 20 to 44% by weight for an initial H4T6/PS ratio and corresponding to the composites B, C, D shown in FIG. 2.

In the same conditions, the scavenging effect for the 270-nm beads shows a completely different behavior. The linear dependency of the initial H4T6 with respect to H4T6 which has undergone scavenging suggests that in the particular case of H4T6 infilling of the space between the closely packed beads is not achieved. Actually, in the operating conditions of the large quantity of H4T6, for filling, it can generate a disordered flocculation (in flocculation conditions) which hides the infilling process. Even in the case of sample E (FIG. 2), obtained by means of 150-nm beads and high concentrations of H4T6, flocculation is the predominant process.

After centrifugation, a wet and homogeneous H4T6/PS deposit (without stratification) is collected. Its volume is approximately 2% of the initial homogeneous suspension. It is capable of dispersing spontaneously in a highly viscous colloidal suspension (hereinafter referenced as colloidal composite) which contains the clusters of H4T6 on dielectric beads.

All the dispersions with both 270- and 150-nm PS are deposited by drop casting directly on silicon oxide substrates.

Depending on the quantity of H4T6 that has undergone scavenging, the dry deposited film of colloidal composite of 150-nm beads has large birefringent dendritic domains (larger than 50 μm). These domains are not observed in H4T6 films without beads or in composites obtained in flocculation conditions, such as the ones obtained with beads having a size of 270 nm or in case E with 150-nm beads.

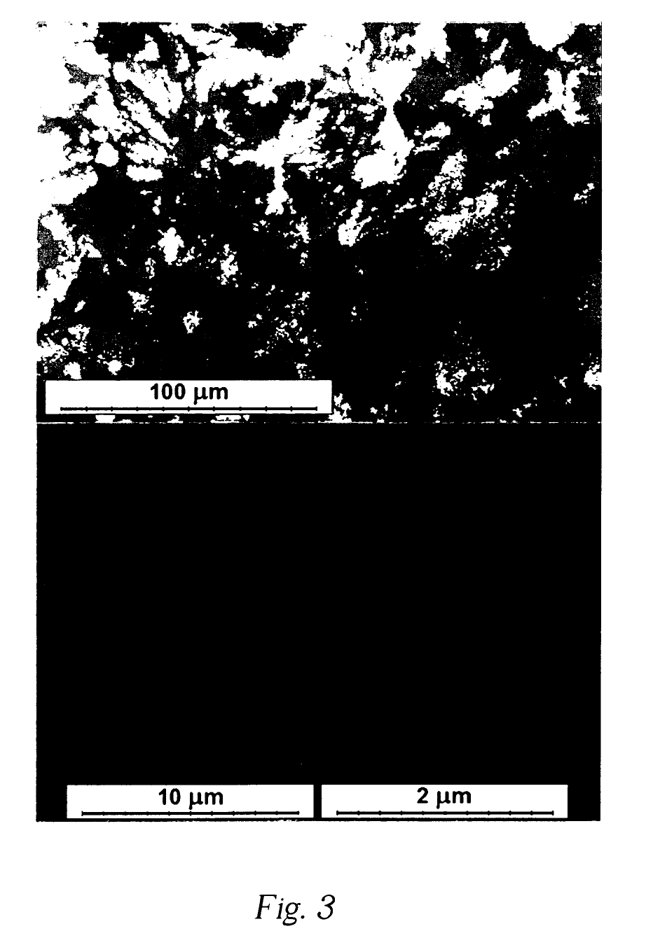

These domains, despite being composed of aggregates of beads immersed in H4T6 (see FIG. 3), are optically anisotropic in polarized light. The extinction of light in each branch at the different polar orientations indicates that the domains behave as a polycrystalline material with different azimuth orientations.

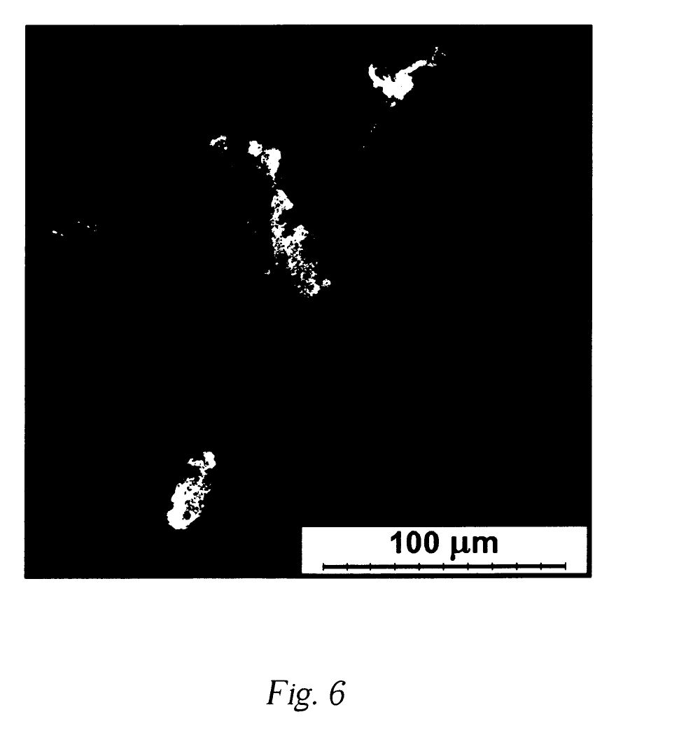

The existence of large domains of H4T6 composites is confirmed by confocal micrography observation at the excitation wavelength of λ=408 nm (supplemental information, FIG. 6).

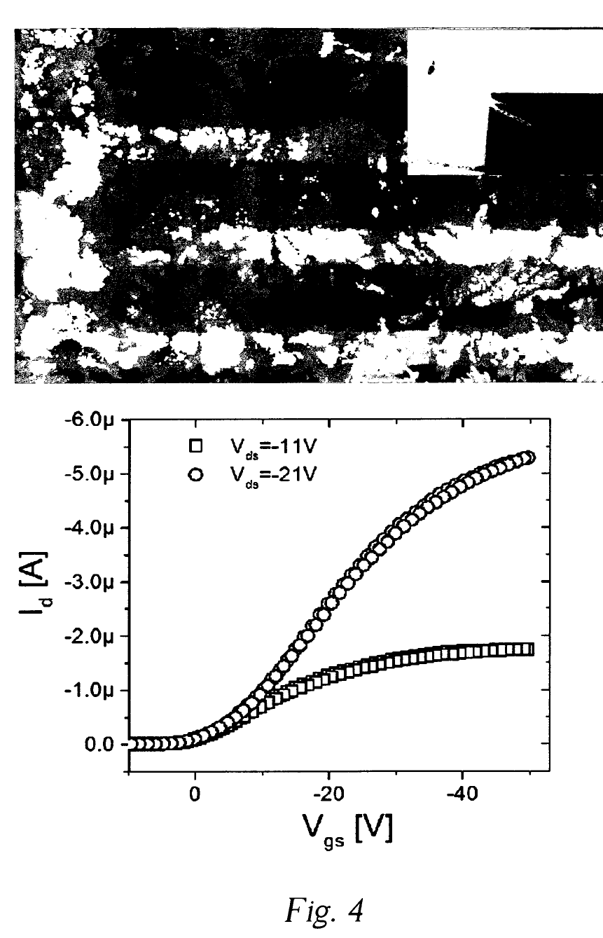

The colloidal composites formed by H4T6 and PS, both having diameters of 150 and 270 nm, were deposited at the top of the test configuration of the contact FET transistors on the bottom in order to measure the response as a transport layer, as shown in FIG. 4.

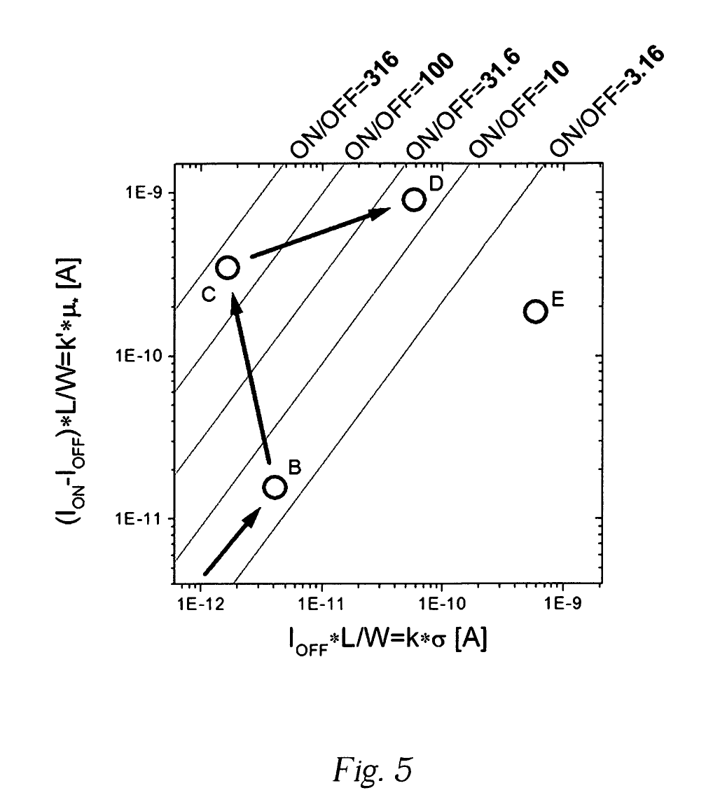

In the case of H4T6/PS composites prepared with 150-nm beads, thorough mapping was performed on all the samples prepared with different H4T6 infilling. A clear FET behavior was observed in the “full infilling” condition of the tight packing structure of PS as shown in FIG. 5b. For all these, a similar electrical characteristic was observed, showing excellent reproducibility and reliability of the method, which is consistent with the fact that the concentration that underwent scavenging is constant and approximately equal to 20% by weight. It should be noted that experimental evidence demonstrates that the composition of the composite, the phases of the semiconductor crystals, the dimensions of the crystals and the distribution are determined geometrically and therefore spontaneously.

FIG. 4 shows the transfer characteristic for a typical transistor fabricated in these conditions. It has a charge field effect mobility of 0.004 cm²V⁻¹s⁻¹ in saturation conditions, and a threshold slope of 4.4 V/decade. The device has low hysteresis, which can be measured with a threshold voltage shift of 260 mV depending on the displacement direction of the gate potential.

The behavior of all the 150-nm series is summarized in FIG. 5. This figure shows the evolution of the factors that compose the ON/OFF ratio with respect to the initial H4T6/PS ratio. Moreover, assuming that 1) the depletion thickness due to the gate field is negligible [14] with respect to the total thickness of the transport layer h, 2) the mobility of the induced carrier is assumed constant, 3) the thickness of the various drops is constant and 4) (V_{gs}−Vₜ)=V_{gs} (V₁ is the threshold voltage); they are correlated to the field effect mobility and to the mass conductance of the composite material (reference should be made to the supporting material).

Initially, the quantity of H4T6 is too low to form an electrical percolation lattice between the well and the source. As a consequence of this evidence, the increase of the initial H4T6/PS (sample B, C) and an evident improvement in the ON/OFF ratio are observed, improving the μ/σ ratio [14]: the apparent field effect mobility of the device increases greatly, but a great variation in mass conductivity is not observed. Subsequently, as demonstrated by item D, a further increase is disadvantageous for the ON/OFF ratio, since it produces a much greater increase in mass conductance with respect to the mobility increase. Finally, item E (FIG. 2 and FIG. 5) is in flocculation conditions and therefore is beyond the scope of our model, which considers composites in which H4T6 arranges itself in the empty space between the beads. In FIGS. 1 and 3, the term “working transistors” is used to designate devices with an ON/OFF ratio of more than 10, since it is too far to be used for any standard practical application.

In the case of composites prepared with 270-nm beads or with 150-nm beads (composite E) in flocculation conditions and the composite A with low H4T6 infilling quantities, no FET behavior was observed within the detection limit, although an equally systematic analysis was performed.

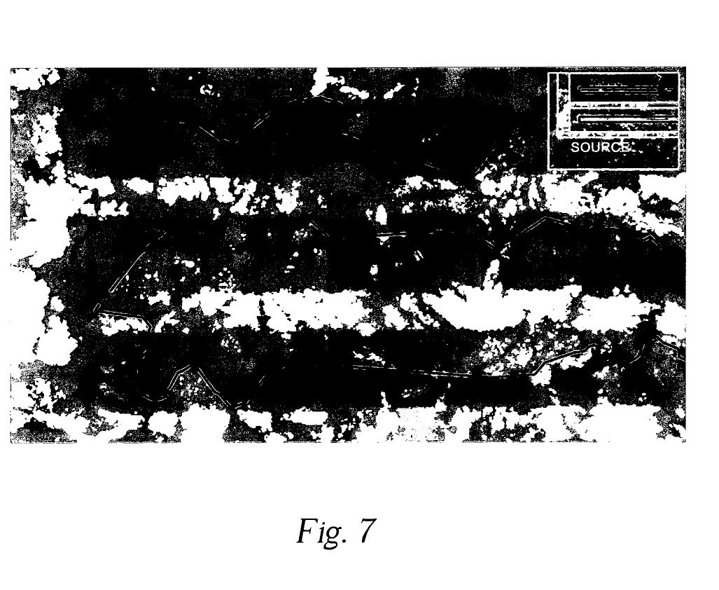

From a morphological standpoint, we found that all the working transistors appear to be greatly covered by composite dendritic domains, the branches of which extend through the channel. Optical images allowed to estimate a coverage on the part of dendritic domains of 60-70% of the channel. This value was found to be highly reproducible. This dendritic morphology is not always correlated to a working transistor, but it has also been observed in samples which have a scarcely FET behavior with a mobility of less than 4×10⁻⁷ cm²V⁻¹s⁻¹). On the contrary, charge transport was observed in transistor channels in which dendritic domains were not found “optically” to form an electrical percolation passage between the well and the source, as shown in the supplemental information of FIG. 7. These experimental data suggest that electrical conduction is not directly correlated to a percolation passage formed by these domains or that the percolation path is produced by a quantity of material which is not detected by optical means or Raman analysis, and only in the case of H4T6/PS which has undergone scavenging below 16% there is no real percolation path. It is worth noting that 16% is considered to be the composition threshold for charge percolation in a conductive/dielectric composite [15].

It is well-established that charge transport is highly anisotropic in conjugated molecules [16] and also depends on the order of the semiconductor molecules. Since the transport layer is limited at most to four molecular layers in contact with the gate dielectric, the working transistor provides real evidence that the molecules of H4T6 assemble in a highly organized layer, at least on the surface of the dielectric. This strongly supports a scenario in which amorphous H4T6 carried by the beads is capable of crystallizing within the geometrical boundaries of the template by slow evaporation of the solvent within the template channel. The variability of domain formation with respect to the diameter of the beads can be due to two process scales: a submicrometer scale, which is set by the beads of the template; and a nanometer scale, which is characteristic of the diffusion/aggregation/crystallization of the H4T6 oligomers. The latter processes should not be influenced critically by mesoscopic self-assembly of the template beads, provided that their characteristic dimensions do not limit the flow or diffusion of the clusters of H4T6. However, in conditions of infilling with H4T6 of the tetrahedral cavities between the beads, the dimensions of this space affect critically the time for solvent evaporation, discriminating different contents of adequate phases and crystal sizes. In working transistors, the morphological and composition characteristic of the mass composite in the FET channel suggests that also at the crystal interface level R and M are in contact with the substrate and are responsible for conduction, as expected by the planar structure of the molecule of H4T6 in both R and M crystalline forms [17].

To conclude, it is assumed that in wet conditions, after/during centrifugation, the template facilitates the organization of H4T6 in the pre-crystalline form [18-20]. The clusters of H4T6 on the beads are capable of flowing within the channels produced by the aggregation of PS and therefore diffuse on the surface before the solution is completely dry and is therefore slowly organized in the region delimited by the beads. The template of beads forms a percolation path by means of a self-organizing geometry and. controls the molecular sorting rate and the subsequent phase selection, allowing the forming of large conducting and birefringent domains.

The field effect transistors according to the present invention, obtained by depositing beads of PS decorated with H4T6 on the transistors, despite the relaxed environmental conditions, have excellent characteristics, with a charge mobility comparable to that measured in sexithienyl OFET grown in OMBD [4].

Moreover, the present invention provides a new method in which, for the first time, a dielectric meso-porous matrix, such as for example self-assembled PS, is used to induce long-range order in an oligomer fraction, such as H4T6.

The disclosures in Italian Patent Application No. MI2006A000104 from which this application claims priority are incorporated herein by reference.

### REFERENCES

[1] Horowitz, G. Organic thin film transistors: From theory to real devices. J. Mater. Res. 19, 1946 (2004).
[2] Dimitrakopoulos, C. D., Malenfant, P. R. L. Organic thin film transistors for large area electronics. Adv. Mater. 14, 99 (2002).
[3] Dinelli, F., Murgia, M., Levy, P. Cavallini, M., Biscarini, F., de Leeuw, D. M. Spatially correlated charge transport in organic thin film transistors. Phys. Rev. Lett. 92, 116802 (2004).
[4] Destri, S., Ferro, D. R., Khotina, I. A., Porzio, W., Farina, A. Tetrahexylsexithiophene: crystal structure and molecular mechanics calculations. Macromol. Chem. Phys. 199, 1973-1979 (1998).
[5] Caruso, F., Lichtenfeld, H., Giersig, M., Möhwald, H. Electrostatic self-assembly of silica nanoparticle—Polyelectrolyte multilayers on polystyrene latex particles. J. Am. Chem. Soc., 120, 8523-8524 (1998).
[6] Radtchenko, I. L., Sulkhorukov, G. B., Gaponik, N., Kornowski, A., Rogach, A. L., Möhwald, H. Core-shell structures formed by the solvent-controlled precipitation of luminescent CdTe nanocrystals on latex spheres. Adv. Mater. 13, 1684 (2001).
[7] Donath, E., Sulkhorukov, G. B., Caruso, F., Devis, S. A., Möhwald, H. Novel hollow polymer shells by colloid-templated assembly of polyelectrolytes. Angew. Chem. Int. Ed. 37, 2202-2005 (1998).
[8] Caruso, F. Nanoengineering of particle surfaces. Adv. Mater. 13, 11 (2001).
[9] Veinot, J. G. C., Yan, H., Smith, S. M., Cui, J., Huang, Q., Marks, T. J. Fabrication and properties of organic light-emitting “nanodiode” arrays. Nano Lett. 2, 333-335 (2002).
[10] Khan, M. A., Armes, S. P. Conducting polymer-coated latex particles. Adv. Mater. 12, 671 (2000).
[11] Kohut-Svelko, N., Reynaud, S., Dedryevre, R., Martinez, H., Gonbeau, D., Francois, J. Study of a nanocomposite based on a conducting polymer: Polyaniline. Langmuir 21,1575 (2005)
[12] Rigaud, J L., Levy, D., Mosser, G., Lambert, O. Detergent removal by non-polar PS—Applications to membrane protein reconstitution and two-dimensional crystallization. Eur Biophys. J. 1998, 27, 305-319.
[13] Dionigi, C., Nozar, P., Di Domenico, D., Calestani, G. A simple geometrical model for emulsifier free polymer colloid formation. J. Coll. Int. Sci. 275, 445-449 (2004).
[14] Brown, A. R., Jarrett, C. P., de Leeuw, D. M., Matters, M. Field-effect transistors made from solution-processed organic semiconductors. Synthetic Metals 88, 37-55 (1997).
[15] Mezzenga, R., Ruokolainen, J., Fredrickson, G. H., Kramer, E. J, Moses, D., Heeger, A. J., Ikkala, O. Templating Organic Semi-conductors via Self-Assembly of Polymer Colloids. SCIENCE, 299, 1872-1874 (2003)
[16] Horowitz, G., Hajlaoui, M E. Mobility in polycrystalline oligothiophene field-effect transistors dependent on grain size. Adv. Mater. 12, 1046 (2000).
[17] Porzio, W., Giovanella, U., Botta, C., Pasini, M., Destri, S., Provasi,C., Rossi, V., Efficient energy transfer in organic thin films by ultra-high vacuum evaporation. Organic Electronics 5, 59-65 (2004)
[18] Hulvat, J. F., Stupp, S. I. Anisotropic properties of conducting polymers prepared by liquid crystal templating. Adv. Mater. 16, 589 (2004).
[19] Jang, J., Oh, J. H. Novel crystalline supramolecular assemblies of amorphous polypyrrole nanoparticles through surfactant templating. Chem. Comm., 2200-2201 (2002).
[20] Jang, J., Hak Oh, J. Fabrication of a highly transpartent conductive thin film from polypyrrole/poly(methyl methacrylate) core/shell nanospheres. Adv. Funct. Mater. 15, 494 (2005).

What is claimed is:

1-32. (canceled)

33. A device comprising a charge transfer channel, wherein said charge transfer channel comprises a composite material, said composite material comprising particles of a dielectric material with interstice voids between them, said interstice voids being filled partially or totally by a semiconductor or conductor material.

34. The device according to claim 33, wherein said dielectric particulate material has an average particle size of less than one micrometer.

35. The device according to claim 33, wherein the precursor of said composite material is in a form selected from the group constituted by solid, colloidal, gel, fog and smoke.

36. The device according to claim 33, wherein said dielectric material is an organic dielectric material, particularly a polymeric dielectric material, more particularly polystyrene or polymethyl methacrylate or mixtures thereof.

37. The device according to claim 33, wherein said dielectric material is an inorganic dielectric material, in particular silicon oxide or aluminum oxide or mixtures and derivatives thereof.

38. The device according to claim 33, wherein said particles of dielectric material have a shape selected from the group constituted by spherical, cubic, polyhedral shapes and shapes derived from spherical, cubic or polyhedral shapes, such as ellipsoid, parallelepiped, fullerene and conglomerates thereof.

39. The device according to claim 33, wherein said semiconductor material or conductor material is a molecular material or a polymeric material.

40. The device according to claim 33, wherein said semiconductor or conductor material is an organic semiconductor or conductor material, in particular an organic semiconductor material selected from the group constituted by functionalized and nonfunctionalized oligo- and polythiophenes with aliphatic chains and/or polar groups, functionalized and nonfunctionalized oligo- and polyacenes with aliphatic chains and/or polar groups, functionalized and nonfunctionalized rubrene with aliphatic chains and/or polar groups, functionalized and nonfunctionalized oligofluorenes with aliphatic chains and/or polar groups, and mixtures, composites and copolymers thereof, such as polyethylene dioxythiophene, poly(3,4,ethylene dioxythiophene), poly(styrene sulfonate), polyanilines doped or not doped with Lewis acids which maintain their solubility, and polypyrroles.

41. The device according to claim 33, wherein said semiconductor or conductor material is an inorganic semiconductor or conductor material, in particular a semiconductor or conductor material selected from the group constituted by transition metal oxides, carbon nanotubes, transition metals dichalcogenides and transition metal particles.

42. The device according to claim 33, wherein said semiconductor or conductor material is in a form selected from the group constituted by amorphous or crystalline clusters, aggregates, fibrils and particles.

43. The device according to claim 33, wherein said composite material comprises said particles of dielectric material and said semiconductor or conductor material in a ratio which is adapted to give said composite material charge transport properties, in particular for the composite with semiconductor a charge carrier mobility>10⁻⁵ cm²Vs⁻¹, and for the composite with a conductor a conductivity>10⁻¹⁰ Scm⁻¹.

44. The device according to claim 33, wherein it is a field effect transistor.

45. The device according to claim 33, wherein it is a diode, in particular a light-emitting diode, or a light-emitting transistor.

46. The use of a composite material as defined in claim 33 to generate a channel of a field effect transistor.

47. The use of a composite material as defined in claim 33 to form a channel of a diode, in particular a light-emitting diode or a light-emitting transistor.

48. A method for manufacturing a device according to claim 33, comprising the step of depositing a mixture of components of said composite material on a solid surface between two or more electrodes, in particular with a deposition technique selected from the group constituted by contact printing, soft lithography, drop casting, inkjet printing, spray-dry, microfluidics and injection.

49. A method for preparing a composite material for use in a device as defined in claim 33, comprising the steps of:
forming a semiconductor or conductor material in the form of particles, clusters, fibrils or aggregates, in a liquid medium which contains a mixture of solvent-nonsolvent for said semiconductor or conductor material, said solvent and said nonsolvent being mixable and containing submicron particles of a dielectric material, said dielectric material being insoluble in said liquid medium, and
separating from said liquid medium containing said particles, clusters, fibrils or aggregates of semiconductor or conductor material and said particles of dielectric material a deposit which forms a colloidal composite;
drying said colloidal composite in suitable temperature and pressure conditions, in particular at ambient temperature and pressure.

50. The method according to claim 49, comprising the steps of:
a. forming a colloidal dispersion of said dielectric particulate material with an average particle size of less than one micron in a liquid in which said dielectric material is insoluble;
b. forming a solution of said semiconductor or conductor material in one or more solvents for said semiconductor or conductor material, said one or more solvents being mixable with said liquid, said semiconductor or conductor material being insoluble in said liquid;
c. mixing said dispersion and said solution, thus obtaining a mixture which contains particles, clusters, fibrils or aggregates of semiconductor or conductor material in a liquid medium which contains said one or more solvents for said semiconductor or conductor material and said liquid, and in which said particles of dielectric material are present; and
d. separating from said mixture a supernatant and a deposited material which forms said colloidal composite material.

51. The method according to claim 50, wherein said semiconductor or conductor material is an organic material.

52. The method according to claim 51, wherein said solution is a supersaturated solution at ambient temperature of said semiconductor or conductor material.

53. The method according to claim 51, further comprising the step of heating said solution and said dispersion before step c) of claim 18 to a temperature at which said semiconductor or conductor material is completely dissolved in said one or more solvents.

54. The method according to claim 53, further comprising the step of bringing said mixture obtained in step c) of claim 50 to ambient temperature before step d) of claim 50.

55. The method according to claim 50, wherein said separation is a separation by centrifugation, filtration or decantation.

56. The method according to claim 49, wherein said one or more solvents are selected from the group constituted by tetrahydrofuran, methanol, ethanol, propanol, isopropanol, butanol and acetone.

57. The method according to claim 49, wherein said dielectric particulate material has a surface area of>1 m²/g.

58. The method according to claim 49, wherein said dielectric material has polar groups on the surface.

59. The method according to claim 49, wherein said dielectric particulate material has an average particle diameter from 1 nanometer to 1 micrometer.

60. The method according to claim 49, wherein said colloidal composite comprises 10 to 50% by weight of said organic semiconductor material with respect to said dielectric particulate material.

61. The method according to claim 50, wherein said dispersion has a concentration of dielectric particulate material>0.01 g/l.

62. The method according to claim 50, wherein said solution has a content of said organic semiconductor material from 0.01 g/l to 1 g/l.

63. The method according to claim 50, wherein said dispersion and said solution are mixed in a weight ratio from 10:90 to 90:10.

64. A composite material obtainable by means of a method according to claim 49.
